(19) United States
(12) Patent Application Publication
(10) Pub. No.: US 2007/0007983 A1
(43) Pub. Date: Jan. 11, 2007

(54) Semiconductor wafer tester

(76) Inventor: Peter C. Salmon, Mountain View, CA (US)

Correspondence Address: Edward N. Bachand;DORSEY & WHITNEY LLP, Suite 1000, 555 California Street, San Francisco, CA, 94104-1513, US

(21) Appl. No.: 11/454,674

(22) Filed: Jun. 16, 2006

Related U.S. Application Data
(63) Continuation-in-part of application No. 11/031,219, filed on Jan. 6, 2005, now abandoned.

(51) Int. Cl. G01R 31/26

(52) U.S. Cl. 324/765

(57) ABSTRACT

A test head is described for simultaneous test and/or burn-in of all of the chips on a semiconductor product wafer. The test head is suitable for testing wafers containing high powered chips such as microprocessors. A stimulus wafer is supported on a base with connections for power plus an interface to a test support computer. Attached to a first face of the stimulus wafer are all of the IC chips required to implement test circuits, power distribution, local memory, temperature sensing, and communication interfaces. The second face of the stimulus wafer is used to attach the first face of the product wafer using compliant connectors. The second face of the product wafer is available for cooling. Advanced flip chip connectors are preferably employed for assembling the chips on the stimulus wafer; they enable rework of any chips that prove defective. Embedded in the stimulus wafer are interconnection circuits plus through-wafer connectors. The product wafer is bumped at the I/O pads. In the stimulus wafer, fine pitch sockets are provided for attaching IC chips at the first face as well as for attaching the bumps of the product wafer at the second face; each socket comprises a well filled with conductive material and the bumps are inserted into the wells. The bumps may be solder balls, conductive pillars, stud bumps, or spring structures. By circulating a cooling fluid against the back side of the product wafer, high rate cooling of 20,000 watts or more can be dissipated in the product wafer.

### RELATED APPLICATIONS

This application is a continuation-in-part of co-pending application Ser. No. 11/031,219 filed Jan. 6, 2005, the entire contents of which is incorporated herein by this reference.

### THE INVENTION

This invention relates to apparatus and methods for testing electronic components, and more particularly to apparatus and methods for simultaneously testing all of the integrated circuit chips on a semiconductor wafer, including high powered chips.

### BACKGROUND OF THE INVENTION

The current practice for testing integrated circuit (IC) chips and the systems using them includes wafer sort at the wafer level, unit test or class test at the packaged unit level, board test at the board level, and system test at the system level. At wafer sort, typically the wafer is tested one chip at a time, using a probe card that steps in sequence across the wafer. The probes typically have inductance that limits the speed of wafer sort testing. Depending on circuit yield, around 10-30% of the total chips are typically defective at wafer sort. The remaining good chips are usually assembled into discrete packages and tested as packaged units, typically at full clock speed. If burn-in is required it is usually performed using packaged parts; they are plugged into sockets on burn-in boards and exercised at temperature and voltage extremes to identify weak chips that may fail prematurely. Packaged parts that survive test and burn-in are assembled onto printed circuit boards (PCBs), and the boards are verified using a board level test. If components prove defective at board test, they may be replaceable using rework procedures; typically this includes melting of the soldered connections so that a defective part can be withdrawn from the board. If the board fails at system test it may be replaced, or it may be repaired using a board level test.

The current invention addresses test apparatus and methods to achieve known good die (KGD), for the case of testing all of the chips on a wafer simultaneously; this is known as “wafer level testing”. Although wafer level testing has been applied for many decades to the preliminary test known as “wafer sort”, it has only recently been applied to high speed functional testing and burn-in. Wafer sort has generally been a serial procedure, wherein the probes in the probe card touch down on one die or a small group of die at a time. In the preferred embodiment of the current invention, all of the die are tested simultaneously, providing improvements in test throughput and in test cost. In this application, “die” may refer to a single integrated circuit chip, or a plurality of chips. The improvement factor is approximately equal to the degree of parallelism, i.e., the number of die on a wafer. Microprocessor chips are chosen as a reference case because they represent a class of IC chips having high power and high speed requirements. A 300 mm semiconductor wafer typically contains around 177 microprocessor chips measuring approximately 18 mm on a side. At 90% yield 159 chips will be functional. Each chip may have 2,000 leads (I/O pads) for example. If a probe card is used to contact such a wafer, it must have 354,000 individual probe tips. This level of complexity in the probe card is expensive to build and is also difficult to maintain. Also, to take advantage of parallel testing, the test environment preferably includes a test channel for each of the probe tips. This massive degree of parallelism is not physically possible because of interference between the large number of probes and because of difficulty fitting the large number of associated wires into the available space. Additionally, ff the logic chips dissipate a substantial amount of power (some microprocessor chips dissipate more than 100 W), then large amounts of heat must be dissipated to prevent melting or burning of the test head. For the case cited above, if each of the 177 microprocessor chips on a product wafer dissipates 120 W the total heat dissipation is 21,240 watts, too much for test heads in current use.

Insertion force is another critical parameter for wafer level testing. For pogo pins and other probes utilizing mechanical flexure, a typical force of 10-20 gm is required for each pin or lead. For the case of 354,000 leads per wafer and 10 grams of insertion force per lead, the total required force is 3,540 kilograms or 7,804 pounds or 3.5 metric tons. This high force is impractical or undesirable for testing a product wafer. The current invention addresses this problem by providing low insertion force connectors. These connectors employ bumps or pillars at each I/O pad on the chip side, and a corresponding well filled with conductive material on the board or substrate side. The conductive material filling the wells may be a liquid, or it may be a dry powder. For example, micron or sub-micron sized particles of gold or gold-tin alloy are suitable, having good flow characteristics. The proposed array of connectors comprises a multi-pin fine-pitch test connector having low insertion force.

In U.S. Pat. No. 5,070,297 to Kwon et al. have described a test probe unit connected between an integrated circuit chip and a test control unit. The test probe unit includes a plurality of probe tips and compliant material assures that the probe tips positively and conductively engage integrated circuit pads of all associated integrated circuits on a wafer.

In U.S. Pat. No. 5,461,327 to Shibata et al. have described a probe apparatus including a test head connecting to a tester through a bundle of leads.

In U.S. Pat. No. 5,701,666 to DeHaven et al. have described a method for manufacturing a stimulus wafer for use in a wafer-to-wafer testing system to test integrated circuits located on a product wafer. A circuit distribution wafer contains circuitry which is used to test the integrated circuits on the product wafers. A connection from the product wafer to the circuit distribution wafer is made via a compliant interconnect medium.

### SUMMARY OF THE INVENTION

The current invention is a tester apparatus and a test method that can be used for parallel testing and/or burn-in of a wafer full of high-powered IC chips. Preferably all of the die on the wafer are provided with parallel and independent paths for both stimulus and response. The test head includes a stimulus wafer assembly, a product wafer, a compliant interface between the stimulus wafer assembly and the product wafer, and a cooling chamber having circulating coolant that directly contacts the back side of the product wafer. The preferred embodiment of the complete test system also includes a computer subsystem, a power supply, and a cooling subsystem. This system can provide “high rate cooling” while supporting functional testing at full chip speed, with preferably all of the chips on the wafer being simultaneously and independently tested.

### BRIEF DESCRIPTION OF THE DRAWINGS

The foregoing and other objects of the invention will be more clearly understood from the accompanying drawings and description of the invention:

FIGS. 1A-1E illustrates in a schematic cross-section a sequence of steps to configure and operate a test head of the current invention.

FIG. 2 shows the topside of a stimulus wafer, including 177 die sites.

FIG. 3 is an expanded view of one of the die sites of FIG. 2, showing an array of wells that functions as a fine pitch test socket.

FIG. 4 illustrates a stimulus wafer in cross-section.

FIG. 5 shows the underside of the stimulus wafer of FIG. 4, including sites for connecting a cable and attaching multiple IC chips.

FIG. 6 is an expanded view of a group of attached chips from FIG. 5.

FIG. 7 is a flow diagram showing control paths and interfaces linking objects of the proposed test system.

FIG. 8 illustrates in a cross-section preferred bump terminals at input/output pads of the product wafer.

FIG. 9 shows in a cross-section preferred well structures on one face of the stimulus wafer assembly, the wells corresponding to the bumps of FIG. 8.

FIG. 10 illustrates in a cross section filling of the wells of FIG. 9 with a conductive powder.

FIG. 11 shows a portion of the compliant interface between stimulus and product wafers in cross section.

FIG. 12 shows in a cross section the effect of melting solder in the wells to form a permanent connection at IC chip attachments.

FIG. 13 shows in a cross section bumps mated with wells, wherein the bumps include bends.

FIG. 14 shows in a cross section solder ball bumps mated with wells.

FIG. 15 illustrates in a cross section bumps in the form of stud bumps, mated with corresponding wells.

### DETAILED DESCRIPTION OF THE PREFERRED EMBODIMENTS

A test pedestal or base of a wafer level test head includes connections to a power source, a test support computer, and a cooling subsystem. Within the test head, test circuits are mounted on a stimulus wafer supported on the base, connected to the power source and the test support computer. An advanced flip chip connector is preferably used on both faces of the stimulus wafer. The first face has attached IC chips that implement a broad range of testing and support functions. The second face includes a compliant interface between the stimulus wafer and the product wafer to be tested. Each flip chip connector preferably includes a male part comprising a conductive element in the form of a bump, and a female part in the form of a well filled with conductive material. The bump may be a straight conductive pillar, a bent wire, a stud bump, a solder bump, or any similar conductive region extending from a chip pad. For brevity, the male portion is referred to herein as a “bump” or a “pillar”. Such a bump is provided at each I/O pad of each mounted chip, and also at each I/O pad of the product wafer. During assembly, the bumps are aligned with and inserted into the wells. The wells connect with interconnect traces of the stimulus wafer and selectively with conductive elements (feedthroughs) passing through the stimulus wafer.

At the compliant interface between the stimulus wafer assembly and the product wafer, the pillars have a length to diameter ratio that provides flexibility in the flip chip connectors in the horizontal plane. The compliant or flexural behavior is capable of relieving shear stresses at chip-to-wafer interfaces or wafer-to-wafer interfaces. The pillars are preferably flexible enough that an epoxy under fill layer is not required to achieve highly reliable chip-to-substrate connections. When formed into springs having a bend in the middle, pillars have increased flexibility for relieving tensile/compressive stresses in the vertical direction. However, the bend is typically not required since a suitably slender straight pillar element will buckle as required to relieve compressive stress. If the stimulus wafer is fabricated from silicon and the attached ICs are also fabricated from silicon, the thermal characteristics of chip and substrate will be matched. However, pillars having adequate flexibility to tolerate mismatched expansion characteristics of different chip or substrate materials are preferred because they can be applied in a standard manner. For chip sizes up to 20 mm on a side, and for power dissipations up to 120 W, an epoxy under layer can usually be avoided with a pillar length of approximately 100 microns and a pillar diameter of approximately 10 microns. The pillars on the chip side terminate in wells on the substrate side. The use of either liquid metal or dry powder as the conductive material in the wells provides a temporary plug-and-socket connection for the duration of the test. Details of a test socket using a liquid conductor in the wells are described in co-pending U.S. patent application, Ser. No. 11/007,720, the entire contents of which is incorporated herein by this reference.

IC chips mounted on the stimulus wafer implement most of the test functions except for some high level functions that are preferably implemented in a test support computer. Preferably the stimulus wafer also has through-wafer interconnects in order to provide short path lengths for both stimulus and response signals, enabling high speed control and sensing of circuits on the product wafer. The stimulus wafer assembly preferably also includes in chip form all of the power distribution circuits required for distributing power locally to each die on the product wafer. These power distribution circuits may include DC-to-DC converters and/or local voltage regulators, in addition to passive arrays of termination resistors and bypass capacitors.

The advanced flip chip connectors are designed to enable replacement of any assembled chips that prove to be defective. Even if 100 or more IC chips are required to implement all of the required test functions, the rework capability allows such a complex assembly to be cost-effectively produced.

Product wafers may contain all variations and combinations of digital, analog, RF, and optical circuits. The method of aligning the product wafer and the stimulus wafer typically employs split beam optics having alignment accuracy of approximately ±1 μm, as is known in the art. A similar alignment method is used for attaching chips to the stimulus wafer.

For the case of a product wafer comprising high-powered chips, a cooling chamber is provided that mates with the test pedestal, including an O-ring seal around the periphery of the product wafer. Water or other fluid coolant is circulated in the cooling chamber during testing; it is in direct contact with the back side of the product wafer and provides a low impedance thermal path between active junctions on the product wafer and the cooling medium. This method is capable of cooling a 300 mm wafer at a rate of 20,000 watts or more, an example of “high rate cooling”. If burn-in is required, it is preferably conducted using the same setup, achieving the desired temperature by controlling the flow of coolant, and also providing the required variations in power supply voltages. The set of locations of chips that pass all tests is preferably recorded in local memory, subsequently up-loaded to a computer (e.g., the “test support computer”) and optionally examined by a test operator through an appropriate human interface.

In a preferred embodiment, water is evacuated from the cooling chamber at the completing of testing, the chamber is removed from the test pedestal, the back side of the product wafer is dried with a jet of air, and the product wafer is removed by withdrawing the bumps from the wells. The product wafer can then be diced and the known good die (KGD) plated in waffle packs or the like in preparation for the next assembly step. Confidence in the KGD tested by this method should be higher than with currently available test methods because the chips have been tested at full speed and full power, while in wafer form.

There are typically at least 150 good die on each 300 mm wafer, even for relatively large sized microprocessor chips. If they are tested in parallel rather than serially, the resulting test throughput will be approximately 150 times greater. Since test time is a primary indicator of test cost, the value of such a parallel tester is approximately 150 times greater than an equivalent serial tester. Additional economies derive from the improved yield of KGD tested using the current invention.

Much of the hardware complexity in a modern integrated circuit tester relates to the “pin electronics”; i.e., the drivers and relays and sense circuits connecting a tester node to a node under test in the product wafer or chip or packaged unit. At wafer test it has generally been difficult to achieve high speed control and sensing because of the physical path length between these nodes, typically including a probe card to provide the necessary mapping of tester connections. In the preferred embodiment of the current invention these path lengths are shorter, resulting in less power required in the driver circuits and easier testing at higher bit rates. This requires development of a custom stimulus wafer for each different chip design; it has well locations that are matched to the particular layout of bumped terminals on the product wafer. Thus, connectivity is provided in the stimulus wafer rather than in a probe card or other probing device or circuit.

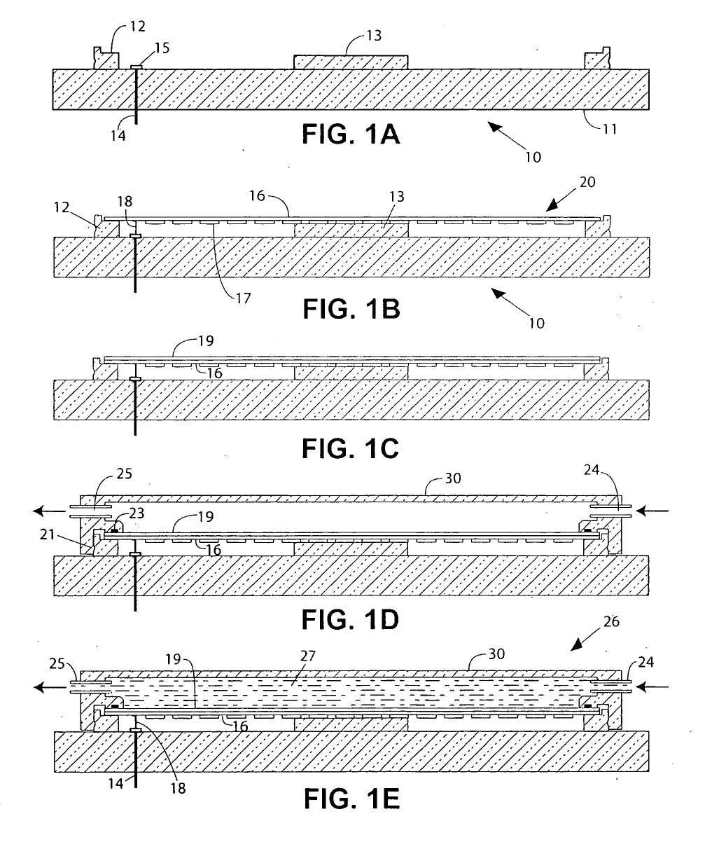

FIGS. 1A-1E detail a sequence of steps to configure and operate a wafer level test head of the current invention. The reference case is assumed: 177 microprocessor die on a bumped 300 mm wafer, with each die dissipating 120 watts of heat. The total heat generated during testing is over 20,000 watts.

FIG. 1A shows a test pedestal 10 including a base plate 11, a support ring 12, a center support 13, and electrical input/outputs 14 terminating in a connector 15. Electrical input/outputs 14 include wires carrying power plus an interface to a test support computer, as will be further described.

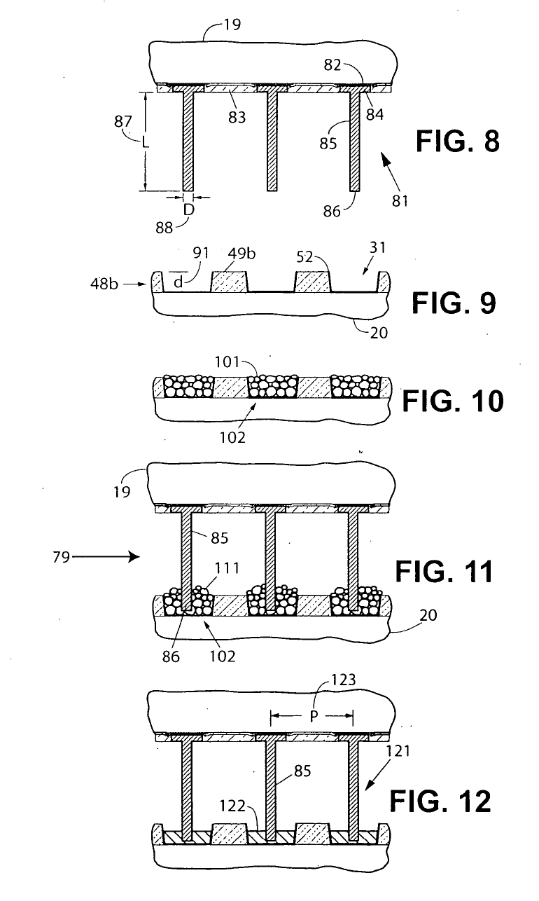

In FIG. 1B stimulus wafer assembly 20 is positioned on pedestal 10 using support ring 12 and center support 13. Stimulus wafer 16 is preferably a semiconductor wafer and has an array of integrated circuit (IC) chips like 17 mounted on a first face, the under side of the wafer. Stimulus wafer assembly 20 refers to the combination of stimulus wafer 16 and attached IC chips 17. These IC chips perform test execution and power distribution functions, as will be further described. They are attached using improved flip chip connectors that allow replacement of any chips that prove defective, as will be further described in reference to FIGS. 8-12. Electrical feeds 18 are preferably implemented in a flex circuit; they start at connector 15 and end pressed against the surface of stimulus wafer 16, making contact with I/O pads. Stimulus wafer 16 has a test socket on its top side, implemented as an array of wells filled with conductive material. The conductive material is preferably a dry powder or a liquid conductor; in either case good electrical connection can be made using low insertion force.

In FIG. 1C a wafer to be tested, called herein the “product wafer” 19, has been aligned to the stimulus wafer assembly, and its bumps have been inserted into the wells presented by the stimulus wafer, to be further described in reference to FIG. 11.

In FIG. 1D a cooling enclosure 30 has been attached to pedestal 10, using an interference fit 21, and including a liquid seal 23 at the periphery of product wafer 19. Liquid seal 23 is preferably accomplished using a flexible gasket such as a compressed O-ring. Inlets 24 and outlets 25 are provided for circulating a cooling fluid.

FIG. 1E shows a completed test head of the current invention 26, including cooling fluid 27 circulating in the cooling enclosure. Not shown is a pumping system that circulates and cools fluid 27. Fluid 27 may be water for example, or any other suitable coolant. Fluid 27 is circulated for the duration of testing, while power is applied to the product wafer. Since water has a specific heat of 4.186 Joules per gram per degree Centigrade, a flow rate of 5 liters per minute will provide over 20,000 watts of cooling if the water temperature rises by 60° C. The cooling medium 27 is thermally well coupled to the product wafer, by circulating directly against its surface. The surface contacted is substantially all of the second or upper face of the product wafer. If burn-in is desired, the flow rate may be adjusted to achieve a desired burn-in temperature, and the power distribution chips attached to stimulus wafer 16 may also be controlled to deliver the required burn-in supply voltages. The power distribution chips may include DC-to-DC converters and/or local voltage regulators.

After testing of the product wafer is complete, test results that have been stored in memory chips attached to the stimulus wafer are interrogated by and transmitted to the test support computer using electrical cables 18 and 14. Using these test results, the test support computer generates a map of good devices on product wafer 19. Cooling fluid 27 is pumped out of cooling chamber 30. The product wafer 19 is dried using a jet of compressed air for example, and removed by withdrawing the bumps from the wells. Since the wells contain a compliant conductor in the form of a liquid or a free-flowing powder, product wafer 19 can be easily separated from stimulus wafer assembly 20. A suction device may be employed to assist in the removal of the product wafer. After removal, the product wafer can be diced, and the good die can be placed in suitable carriers such as waffle packs, ready for the next assembly operation.

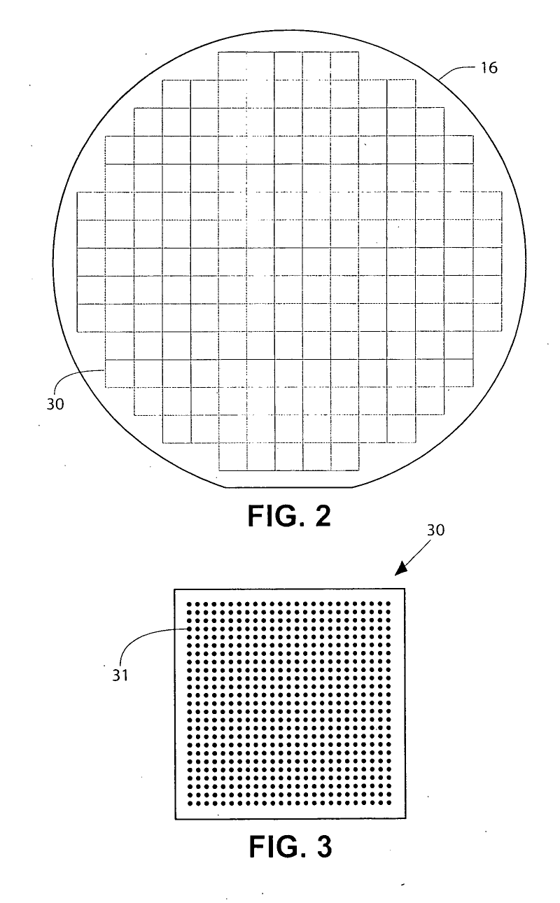

FIG. 2 illustrates the top surface of stimulus wafer 16, including 177 socket arrays 30, corresponding to 177 microprocessor die on the wafer to be tested in the reference case previously presented.

FIG. 3 is an expanded view of socket array 30, showing an array of wells 31; each well is preferably filled with a compliant conductor.

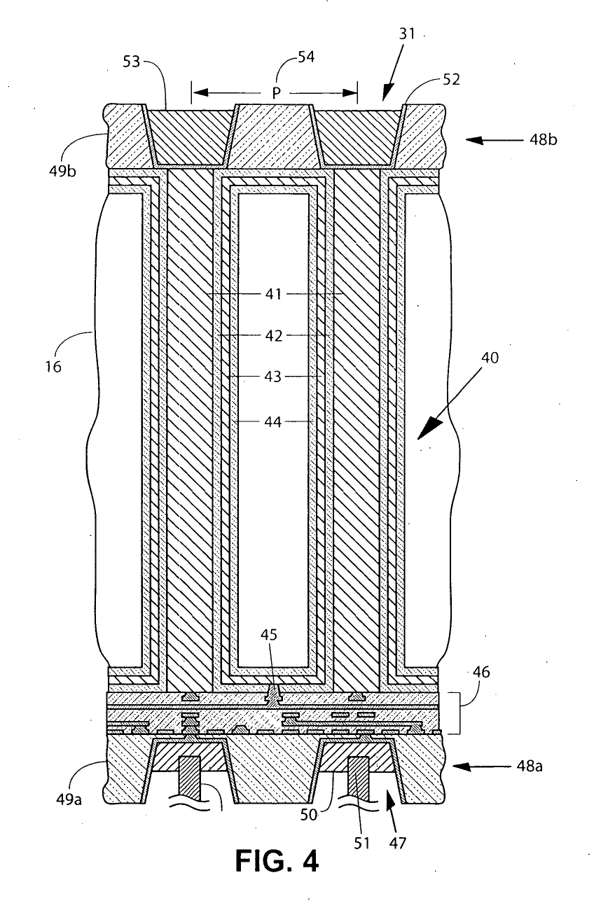

FIG. 4 shows a preferred method for providing through wafer interconnects for stimulus wafer 16 of FIG. 1, using polysilicon feedthroughs 40. The preferred embodiment employs silicon as the stimulus wafer substrate. This method follows the work of Eugene M. Chow et al, “Process Compatible Polysilicon-Based Electrical Through-Wafer Interconnects in Silicon Substrates”, Journal of Micro-electro-mechanical Systems, Vol. 11, No. 6, December 2002. The process has been developed for polysilicon pillars having a diameter of 20 μm in a wafer 400 μm thick. Each feedthrough 40 includes a central polysilicon column 41, surrounded by a first isolation layer of silicon dioxide 42, surrounded by a screen conductor layer 43 of deposited polysilicon, and finally a second isolation layer of silicon dioxide 44. Each feedthrough 40 has a typical resistance of 10-14 ohms and typical capacitance of 1 picofarad, enabling high speed signaling through the wafer. For high current signals and for power supplies, multiple feedthroughs can be used in parallel. Screen 43 is typically connected to ground using a via like 45.

As discussed in reference to FIG. 1, stimulus wafer assembly 20 has attached chips at its bottom surface and wells providing a test socket at its top surface. In addition to the feedthroughs or through wafer interconnects 40, multilayer interconnection circuits 46 are provided in additive layers at the bottom face of stimulus wafer 16, using metal and dielectric layers as is known in the art. Interconnection circuits 46 provide the means to map between selected I/O points on the bottom surface, such as well 47, and I/O points on the top surface such as well 31, first shown in FIG. 3. After interconnection circuits 46 have been fabricated, assembly layer 48a is fabricated as shown, preferably using photo-defined BCB 49a as is known in the art. Reflowed solder 50 binds the ends 51 of the bumps provided at I/O pads on all of the attached IC chips. At the top of the wafer, conductive walls 52 typically comprise a layer of aluminum that bonds with the exposed polysilicon pillar 41 followed by a sequence of layers that terminates in a non-oxidizing surface layer that is compatible with the chosen compliant conductor used in the wells. A suitable sequence of layers may comprise sputtered or evaporated aluminum, sputtered titanium/copper and plated nickel followed by plated gold. The compliant conductor 53 may be a liquid or a dry power. A suitable liquid metal alloy may include a base of gallium, indium to lower the melting point, antimony to reduce oxidation, and bismuth to improve fluidity. A suitable dry powder may be comprised of fine particles of a gold-tin alloy such as 80Au20Sn. The particle diameter may be sub-micron, or the particles may be nanoparticulates. A preferred diameter range is 0.1-10 μm. This choice of conductive alloy has the advantage that it can also be used as a fluxless solder. Particles formed from the gold alloy material have a low tendency to oxidize; they can be cleaned for use as a fluxless solder by brief immersion in dilute hydrochloric acid. The pitch of wells 31 will correspond to the pitch of bumps used on the product wafer. The minimum pitch P, 54 may be less than 80 μm for example, if 10 μm diameter copper pillars or posts are used for the bumps. Selection of the type of bump used will depend on the pitch as well as other factors.

Stimulus wafer 16 may include embedded passive circuits, typically used for improving the signal integrity of high edge-rate signals flowing in the embedded traces and feedthroughs. The passive circuits may include termination resistors or bypass capacitors. Required active circuits are preferably contained in attached IC chips. By not implementing active circuits in stimulus wafer 16, fewer masking steps will be required and the wafer can be fabricated relatively inexpensively, potentially on older fabrication lines.

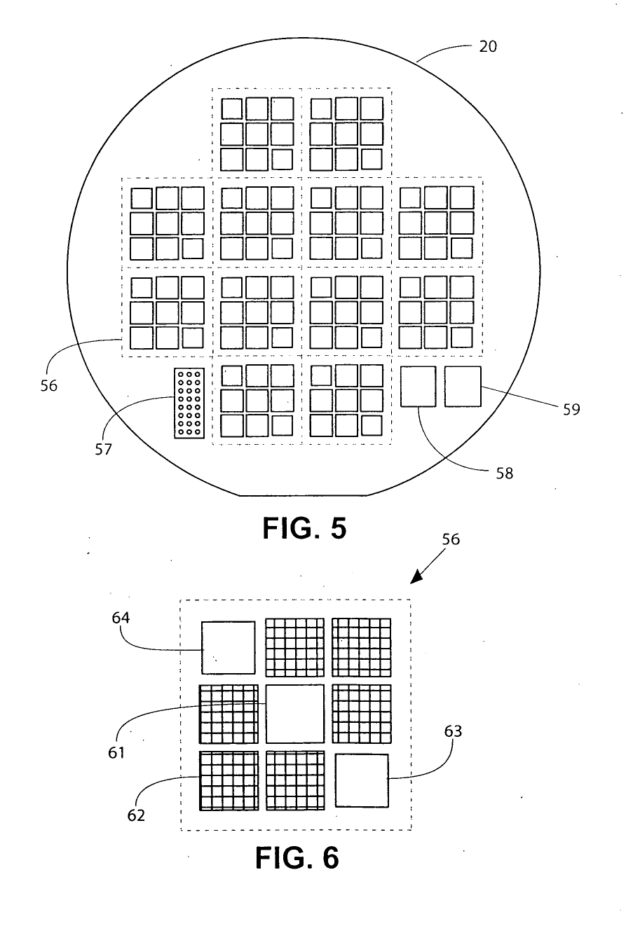

FIG. 5 depicts a first face or bottom side of stimulus wafer assembly 20, including multiple locations 56 of a test cluster, to be further described in reference to FIG. 6. Also included is an I/O pad array 57 for connecting the flex circuit 18 of FIG. 1E, carrying I/O signals and power between stimulus wafer assembly 20 and the test support computer. A test controller chip 58 is also shown; its purpose is to support the interface between the test support computer and the multiple test clusters 56. Test controller chip 58 accesses local memory chip 59 for buffering test inputs and outputs and storing intermediate and final results.

FIG. 6 shows an expansion of test cluster 56, including master chip 61, multiple slave chips 62, a power distribution chip 63, and a cluster interface chip 64. Master chip 61 provides test vectors to slave chips 62 which provide test input/output functions (pin electronics) for the large number of inputs and outputs associated with the circuits on the product wafer. The pin electronics typically include registers for holding test vectors and test results, and comparators for comparing each bit within a test vector against a corresponding bit containing a known good value. Power distribution chip 63 is preferably digitally controlled; it accepts commands and meters local power supply voltages and currents that vary as required for the various tests, optionally including burn-in. Cluster interface chip 64 interfaces master chip 61 in each test cluster to test controller chip 58 at the wafer level; it also preferably includes temperature sensing circuits, for localized temperature monitoring of the circuits under test.

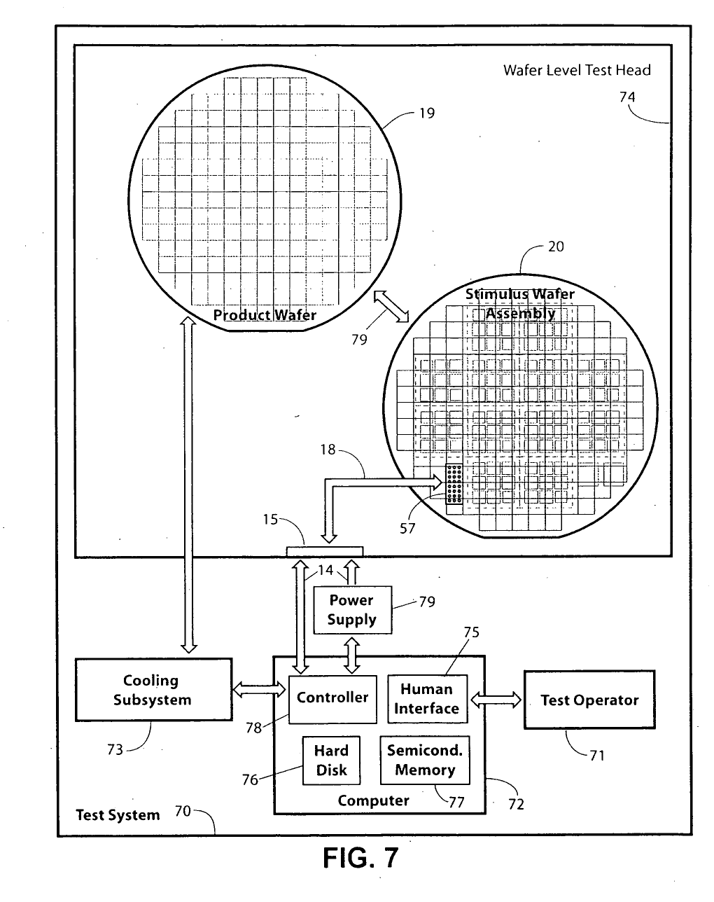

FIG. 7 is a control flow for test system 70, including computer 72, cooling subsystem 73 and wafer level test head 74. An operator 71 is optionally included. Test operator 71 may interact with computer 72 using human interface 75 as is known in the art, typically including a keyboard and a display monitor. Computer 72 typically includes a hard disk 76 and semiconductor memory 77 that service controller 78. Controller 78 provides sequencing for starting and stopping the test, pausing for data transfers if required, and it also controls cooling subsystem 73 and power supply 79. Controller 78 communicates via cable 14 of FIG. 1, connector 15, flex cable 18, and I/O pad array 57 with test controller chip 58 on the stimulus wafer assembly 20. Cooling subsystem 73 is controlled by controller 78 and delivers coolant at a predetermined temperature and flow rate to the product wafer, and returns the heated cooling medium to the cooling subsystem. Product wafer 19 is interfaced to stimulus wafer assembly 20 through compliant interface 79. The test architecture described in FIG. 7 is just one example of many possible implementations of the proposed apparatus and method. It shows a practical implementation of a wafer level tester that can provide full speed functional testing at gigabit per second rates while cooling the product wafer at 20,000 watts or more.

The compliant interface 79 between the stimulus wafer assembly 20 and the product wafer 19 will now be discussed. FIG. 8 shows a portion of product wafer 19 of FIG. 1 having flip chip bumps in the form of conductive pillars 81. The pillars are preferably built up from I/O pads 82; the pads are accompanied by openings in passivation layer 83. An under bump metallization (UBM, not shown) preferably covers each I/O pad and provides a good metallurgical transition between the pad and the base 84 of the pillar, absent of brittle inter-metallic compounds. A preferred sequence of UBM includes a titanium adhesion layer followed by a seed layer of copper; both layers having a thickness of 50-80 nm. Conductive pillar 81 includes a base 84 and a post 85. The post 85 may be circular or rectangular in cross-section. The copper base 84 and post 85 are built up from the copper seed layer, using photolithographic and electroplating methods known in the art. Pillar base 84 provides a strong attachment to input/output pad 82. A preferred post diameter 88 is 10 μm and a preferred post length 87 is 100 μm.

FIG. 9 shows stimulus wafer assembly 20 having wells 31 of FIGS. 3 and 4 fabricated in assembly layer 48b formed from dielectric material 49b such as benzo cyclo butene (BCB). The BCB is preferably photo-defined, by exposing with ultra-violet radiation through a mask as is known in the art. A suitable depth d, 91 for the wells is 20-50 μm with 30 μm preferred. Wells 31 have conductive walls 52 that were previously described in reference to FIG. 4.

In FIG. 10, the preferred embodiment includes a fine dry powder 101 in the wells. The preferred powder is a particulate formed from 80Au20Sn alloy. The wells are preferably filled by pouring the conductive powder onto the upper surface of stimulus wafer assembly 20, and briefly applying a tacky film to remove excess particles. A filled well is labeled 102.

FIG. 11 shows the effect of aligning product wafer 19 with the second face or upper side of stimulus wafer assembly 20, and inserting the posts 85 of conductive pillars 81 into the wells 102. A preferred alignment method employs split beam optics, achieving alignment accuracy of around ±1 μm, as is known in the art. Insertion of the bumps in the wells is a gentle process because the powder is free-flowing. The required insertion force is only slightly greater than the force of gravity on the product wafer. An alternate insertion method is to provide ultrasonic shaking of the test head base plate 11 after centering the ends 86 of the posts 85 atop the wells of dry powder 102. The ultrasonic shaking will cause the posts 85 to penetrate the dry powder material without adding any force other than gravity acting on the product wafer. A gentle insertion is particularly important for recent semiconductor wafers that employ fragile low-k dielectrics. As end 86 of post 85 of pillar 81 penetrates the powder, some particles 111 are displaced upward as shown. After testing of the product wafer is complete and a map of the good die has been recorded, and coolant has been removed from the test head, posts 85 can be withdrawn from the wells and the product wafer removed from the test head. The product wafer can then be passed to the next step in the manufacturing process, such as dicing to create individual IC chips.

We now turn our attention to the method for attaching IC chips to the first face or underside of the stimulus wafer. The same process that was taught in the preceding paragraphs for temporarily attaching the product wafer to the stimulus wafer, described in reference to FIGS. 8-11, is also used for attaching individual IC chips, except that an additional step is required. FIG. 12 shows the effect of heating and melting the conductive dry powder to form a solid and semi-permanent connection 121 of a pillar in a well; the connection is permanent unless it is subsequently reworked. During fabrication of the stimulus wafer assembly 20, this process step can be performed on a hot plate, using a peak temperature of approximately 320° C. for melting the preferred 80Au20Sn alloy. Posts 85 are captured in solid alloy 122 as shown, providing a strong electrical, mechanical, and thermal connection. The minimum pitch P 123 is around 80 μm in the preferred embodiment, fine enough to handle all anticipated pitches of bonding pads on the attached IC chips such as 17 of FIG. 1. Compared with a typical solder ball attachment, permanent connection 121 is smaller in size, lower in inductance, and has a stronger mechanical attachment. It has flexibility for relieving stress in multiple directions, resulting in no need for epoxy under fill. By thoroughly relieving mechanical stresses, the attached chips will remain flat rather than bowed. By eliminating the need for under fill, viable rework options will exist for replacing chips that prove to be defective. Additionally, good electrical and mechanical connection can be achieved over a range of insertion depths of posts 85 in wells filled with powder 102. Using a preferred well depth of 30 μm, variations of around 10 μm in penetration depth are acceptable. A larger range of acceptable penetration depth can be provided if necessary, using deeper wells. Vertical tolerance of posts 85 in filled wells 102 helps to avoid problems arising from imperfectly thinned or planarized wafers. This vertical tolerance and adjustability contrasts with the planarity problems associated with solder ball connections; lacking compliant elements the solder balls typically require a diameter accuracy of around ±1 μm to achieve adequate planarity for reliable connections. This planarity is required both at the tips of the bumps, and at the surface of the lands on the receiving substrate, to which the solder balls attach.

The availability of a suitable rework process for attaching IC chips to the stimulus wafer is critical to the current invention. If a viable rework process is not available, the proposed stimulus wafer will be un-manufacturable due to yield issues: specifically the need to reject the stimulus wafer assembly if even one of the attached chips is defective. In the preferred embodiment, rework of chips such as 17 attached to the stimulus wafer assembly 20 can be performed as follows. The stimulus wafer assembly is heated on a hot plate to a temperature of approximately 260° C. The defective chip is then further heated from above using a shrouded source of hot inert gas that is directed at the defective chip but not at its neighbors. When the conductive material or solder melts in the wells under the defective chip, the chip is withdrawn and discarded. The remaining hot solder in the wells is preferably sucked out by the rework tool. The emptied wells are then refilled with dry powder and a replacement chip is attached using the process described above.

Since copper is a ductile material, posts 85 can be readily deformed without breaking or cracking, with end 86 moving as required relative to the pillar base 84. Deformation of posts 85 may occur by moving end 86 in the lateral or horizontal direction as well as in the longitudinal or vertical direction, as required to relieve stresses at the chip-to-substrate interface. To avoid cracking of the pillar due to fatigue caused by repetitive bending cycles, copper deformation is preferably limited to the elastic range. This will be achieved in practice for most applications if the length of posts 85 is around 100 μm and their diameter is around 10 μm, as in the preferred embodiment.

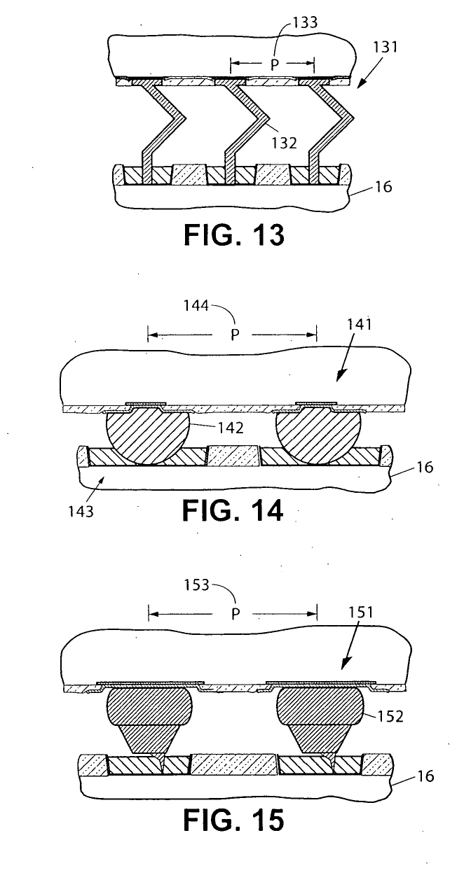

FIGS. 13-15 illustrate the use of different kinds of bumps that may be used on the product wafer 19 and on the attached IC chips 17. FIG. 13 illustrates copper pillars 131 that have a bend 132 in the middle. A typical minimum pitch 133 for this construction is 80 μm.

FIG. 14 shows flip chip connectors 141 that use solder bumps 142. Wells 143 are expanded in the horizontal direction to accommodate the relatively large solder balls. The minimum diameter of such solder balls is typically around 100 μm, leading to a minimum pitch 144 of 150-200 μm.

FIG. 15 shows flip chip connectors 151 that use gold stud bumps 152. A typical minimum pitch 153 for this construction is 100 μm.

The wafer level tester described herein does not require serialized communication between the test circuits and each of the die on the wafer. Nor are the die necessarily grouped for communication purposes. No multiplexers are required. Rather, all of the die can be accessed and tested simultaneously and in parallel.

The preferred embodiment of the current invention employs a stimulus wafer and a product wafer in face-to-face relation, enabling short signal traces for communication between them without using a cable. This arrangement enables high-speed functional testing of the product wafer without the degradation in signaling speed that accompanies the use of a cable for communicating stimulus and response signals between the stimulus wafer and the product wafer.

The preferred embodiment of the current invention also includes a thermal path of low impedance between the product wafer and the coolant. The re-circulating coolant is in direct contact with substantially all of one face of the product wafer. This low impedance thermal path enables operation of the wafer tester and precise testing of the product wafer while power is dissipated in the product wafer at a level of 20,000 watts or higher.

1. For stimulating a semiconductor product wafer a stimulus wafer assembly comprising:
a substrate having a first and a second face;
power and control terminals on said first face for connecting to external devices; integrated circuit chips attached to said first face at test circuit input/output points;
conductive feed throughs in said substrate having terminals at said second face for connecting with said product wafer, and,
interconnection circuits in said substrate that provide connections between said power and control terminals and selected ones of said test circuit input/output points, and between selected input/output points and selected ones of said feed throughs.

2. The stimulus wafer assembly of claim 1 wherein said substrate is a semiconductor wafer.

3. The stimulus wafer assembly of claim 1 wherein one of said external devices is a computer.

4. The stimulus wafer assembly of claim 1 wherein each of said terminals for connecting with said product wafer comprises a well filled with conductive material.

5. The stimulus wafer assembly of claim 4 wherein said conductive material in said wells comprises a conductive powder.

6. The stimulus wafer assembly of claim 5 wherein said conductive powder is a nanoparticulate.

7. The stimulus wafer assembly of claim 5 wherein said conductive powder is formed from an alloy of gold and tin.

8. For testing a semiconductor product wafer a test head comprising: a base;
a stimulus wafer assembly mounted on said base;
compliant connections between said stimulus wafer assembly and said product wafer; and,
a cooling fluid circulating in contact with one face of said product wafer.

9. The test head of claim 8 wherein said compliant connections each comprise a bump and a well.

10. The test head of claim 8 and further including an interface to a control device.

11. For testing a semiconductor product wafer a test system comprising:
a computer having a human interface and a controller;
a power supply connected to said controller;
a cooling subsystem connected to said controller;
a test head having a stimulus wafer assembly connected to said power supply and to said controller;
a compliant interface between said stimulus wafer assembly and said semiconductor product wafer;
wherein said product wafer is cooled by said cooling subsystem while being tested by said stimulus wafer assembly.

12. The test system of claim 11 wherein said cooling subsystem provides a coolant that circulates in contact with a face of said product wafer.

13. The test head of claim 11 wherein said compliant interface comprises a plurality of connectors, each connector comprising a bump and a well.

14. A method for testing a semiconductor product wafer comprising the steps of: providing a stimulus wafer assembly;
attaching said product wafer to said stimulus wafer assembly using compliant connectors; and,
stimulating said product wafer and collecting responses from said product wafer using said stimulus wafer assembly and said connectors, while circulating a cooling fluid against one face of said product wafer.

15. A temporary flip chip attachment comprising:
a semiconductor chip or wafer;
a substrate to which said chip or wafer is to be temporarily or permanently attached; conductive pillars formed at input/output pads of said chip or wafer:
wells filled with a conductive powder at terminals of said substrate, one of said wells provided for each one of said conductive pillars;
wherein said pillars are aligned with and inserted into said wells filled with said conductive powder to form said temporary flip chip attachment.

16. A method for forming a temporary flip chip attachment comprising the steps of: providing a semiconductor chip or wafer;
providing a substrate to which said chip or wafer is to be temporarily or permanently attached;
providing conductive pillars at input/output pads of said chip or wafer;
providing in said substrate a well for each one of said conductive pillars; substantially filling said wells with conductive powder; and
inserting said pillars into said wells.

17. The method of claim 16 wherein said insertion of said pillars in said wells is accomplished by gravity and by shaking of said substrate.

18. The method of claim 16 and including the steps of heating said powder in said wells until it melts, and subsequently cooling to form said permanent attachment.
